(19) United States
(12) Patent Application Publication
(10) Pub. No.: US 2024/0332186 A1
(43) Pub. Date: Oct. 3, 2024

(54) SEMICONDUCTOR DEVICE

(71) Applicant: SAMSUNG ELECTRONICS CO., LTD., Suwon-si (KR)

(72) Inventor: Jinbum KIM, Suwon-si (KR)

(21) Appl. No.: 18/609,065

(22) Filed: Mar. 19, 2024

(30) Foreign Application Priority Data
Mar. 31, 2023 (KR) 10-2023-0042917

(51) Int. Cl. H01L 23/528; H01L 23/48; H01L 29/06; H01L 29/417; H01L 29/423; H01L 29/775; H01L 29/786

(52) U.S. Cl. CPC H01L 23/5286; H01L 23/481; H01L 29/0673; H01L 29/41725; H01L 29/42392; H01L 29/775; H01L 29/78696

(57) ABSTRACT

A semiconductor device includes a substrate having opposite first and second surfaces, a fin-type active pattern on the first surface of the substrate, a gate structure intersecting the fin-type active pattern, a source/drain region on the fin-type active pattern at a side of the gate structure, a contact structure connected to the source/drain region, a buried conductive structure electrically connected to the contact structure and extending in a direction perpendicular to the first surface, and a conductive through structure extending from the second surface of the substrate toward the first surface of the substrate and contacting with the buried conductive structure, the conductive through structure has a first width at a level adjacent to the first surface, narrower than a second width at a level adjacent to the second surface.

### CROSS-REFERENCE TO RELATED APPLICATION

This application claims benefit of priority to Korean Patent Application No. 10-2023-0042917, filed on Mar. 31, 2023, in the Korean Intellectual Property Office, the disclosure of which is incorporated herein by reference in its entirety.

### BACKGROUND

### 1. Field

The present disclosure relates to a semiconductor device.

### 2. Description of the Related Art

In various semiconductor devices, e.g., a logic circuit and a memory, active regions, e.g., a source and a drain, may be connected to a metal wiring of a back end of line (BEOL) through a contact structure. The contact structure may be a conductive through structure penetrating through a semiconductor substrate to connect to the BEOL.

### SUMMARY

According to an aspect of the present disclosure, there is provided a semiconductor device including a substrate having a first surface and a second surface opposing each other; a fin-type active pattern extending from the first surface of the substrate in a first direction; a gate structure extending in a second direction, intersecting the first direction, and intersecting the fin-type active pattern; a source/drain region disposed on the fin-type active pattern at a side of the gate structure; an interlayer insulating unit disposed on the substrate and configured to cover the source/drain region; a contact structure penetrating through the interlayer insulating unit and connected to the source/drain region; a buried conductive structure electrically connected to the contact structure and extending in a direction perpendicular to the first surface of the substrate inside the interlayer insulating unit; a conductive through structure extending from the second surface of the substrate to the first surface of the substrate, coming into contact with the buried conductive structure, and having a first width at a point adjacent to the first surface wider than a second width at a point adjacent to the second surface, wherein a portion in which the buried conductive structure and the conductive through structure are in contact with each other has a continuous side surface; and a power transmission line disposed on the second surface of the substrate and connected to the conductive through structure.

According to an aspect of the present disclosure, there is provided a semiconductor device including a substrate having a first surface and a second surface opposing each other; a fin-type active pattern extending from the first surface of the substrate in a first direction; a gate structure extending in a second direction, intersecting the first direction, and intersecting the fin-type active pattern; a source/drain region disposed on the fin-type active pattern at a side of the gate structure; an interlayer insulating unit disposed on the substrate and configured to cover the source/drain region; a contact structure penetrating through the interlayer insulating unit and connected to the source/drain region; a buried conductive structure electrically connected to the contact structure and extending in a direction perpendicular to the first surface of the substrate inside the interlayer insulating unit; a conductive through structure penetrating through the substrate and extending toward the interlayer insulating unit to come into contact with the buried conductive structure, wherein an upper surface thereof in contact with the buried conductive structure is a convex surface, and a portion extending to the interlayer insulating unit of the conductive through structure has a side surface continuous with the buried conductive structure, and a power transmission line disposed on the second surface of the substrate and connected to the conductive through structure.

According to an aspect of the present disclosure, there is provided a semiconductor device including a substrate having a first surface and a second surface opposing each other; a fin-type active pattern extending from the first surface of the substrate in a first direction; a gate structure extending in a second direction, intersecting the first direction, and intersecting the fin-type active pattern; a source/drain region disposed on the fin-type active pattern at a side of the gate structure; an interlayer insulating unit disposed on the substrate and configured to cover the source/drain region; a contact structure penetrating through the interlayer insulating unit and connected to the source/drain region; a buried conductive structure electrically connected to the contact structure and extending into the substrate from the interlayer insulating unit; a conductive through structure extending from the second surface of the substrate and coming into contact with the buried conductive structure, wherein an upper surface thereof in contact with the buried conductive structure is a non-flat surface, and the conductive through structure has a side surface continuous with a portion disposed in the substrate of the buried conductive structure; and a power transmission line disposed on the second surface of the substrate and connected to the conductive through structure.

### BRIEF DESCRIPTION OF DRAWINGS

Features will become apparent to those of skill in the art by describing in detail exemplary embodiments with reference to the attached drawings, in which:

FIG. 1 is a plan view illustrating a semiconductor device according to an example embodiment of the present disclosure;

FIG. 2 is a cross-sectional view taken along line I-I′ and line II-II′ of the semiconductor device illustrated in FIG. 1;

FIG. 3 is a partial enlarged view illustrating region “A1” of the semiconductor device illustrated in FIG. 2;

FIG. 4 is a cross-sectional view illustrating a semiconductor device according to an example embodiment of the present disclosure;

FIG. 5 is a partial enlarged view illustrating region “A2” of the semiconductor device illustrated in FIG. 4;

FIG. 6 is a cross-sectional view illustrating a semiconductor device according to an example embodiment of the present disclosure;

FIG. 7 is a partial enlarged view illustrating region “A3” of the semiconductor device illustrated in FIG. 6;

FIG. 8 is a cross-sectional view illustrating a semiconductor device according to an example embodiment of the present disclosure;

FIG. 9 is a partial enlarged view illustrating region “A4” of the semiconductor device illustrated in FIG. 8;

FIG. 10 is a plan view illustrating a semiconductor device according to an example embodiment of the present disclosure;

FIG. 11 is cross-sectional views taken along line I-I′ and line II-II′ of the semiconductor device illustrated in FIG. 10;

FIG. 12 is an enlarged cross-sectional view illustrating region “A5” of the semiconductor device illustrated in FIG. 11;

FIGS. 13A to 13E are cross-sectional views of stages in a method of manufacturing the semiconductor device illustrated in FIG. 4; and

FIGS. 14A to 14C are cross-sectional views of stages in the method of manufacturing the semiconductor device illustrated in FIG. 4.

### DETAILED DESCRIPTION

Hereinafter, example embodiments of the present disclosure will be described with reference to the accompanying drawings.

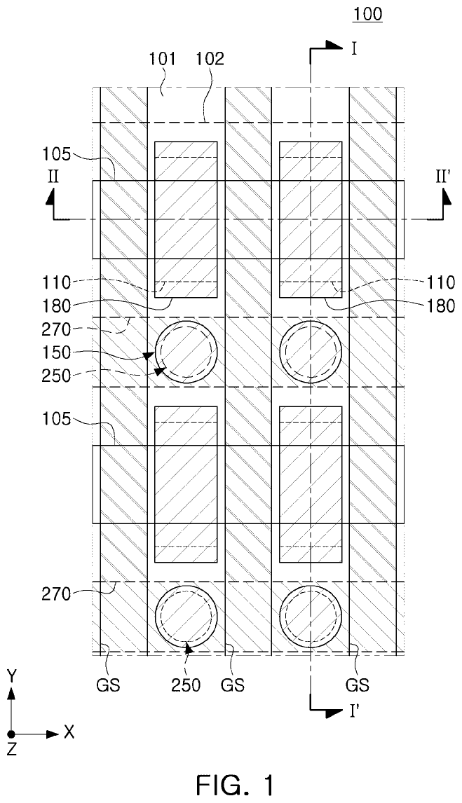

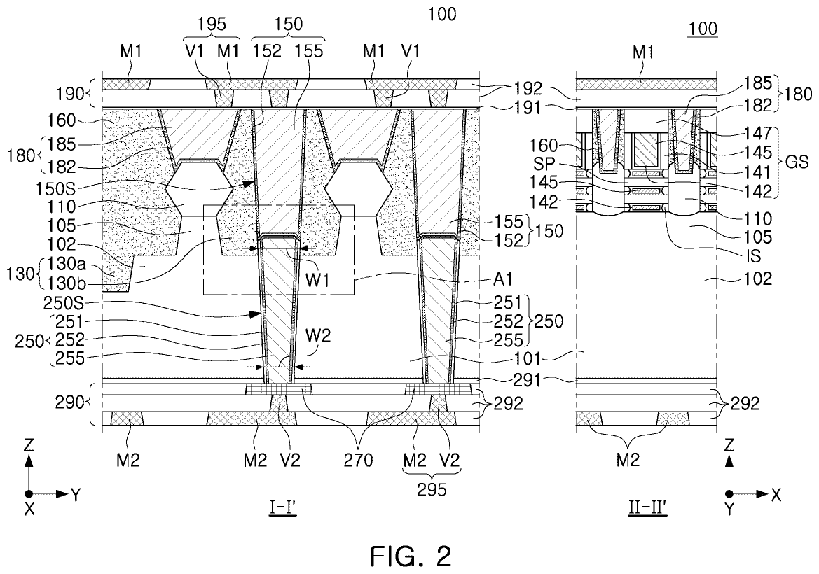

FIG. 1 is a plan view illustrating a semiconductor device according to an example embodiment of the present disclosure. FIG. 2 is a cross-sectional view taken along line I-I′ and line II-II′ of the semiconductor device illustrated in FIG. 1. Here, for convenience, first and second wiring structures 190 and 290 are not illustrated in FIG. 1.

Referring to FIGS. 1 and 2, a semiconductor device 100 according to an example embodiment may include a substrate 101 having a first surface on which an active region 102 is formed and a second surface disposed opposite the first surface. A fin-type active pattern 105 extending (e.g., lengthwise) in a first direction (e.g., an X-direction) on the active region 102, a gate structure GS extending (e.g., lengthwise) in a second direction (e.g., a Y-direction) intersecting the fin-type active pattern 105 and intersecting the first direction (e.g., the X-direction), and a source/drain region 110 disposed on the fin-type active pattern 105 on both (e.g., opposite) sides of the gate structure GS may be formed on the substrate 101.

The semiconductor device 100 according to an example embodiment may include a buried conductive structure 150 electrically connected to the source/drain region 110, and a conductive through structure 250 connected to the buried conductive structure 150 through the substrate 101. The conductive through structure 250 may receive power from a power transmission line 270 disposed on a backside of the substrate 101, i.e., on the second surface of the substrate 101 facing away from the buried conductive structure 150, and may transmit the power to an element region (e.g., to the source/drain region 110). A structure of a power delivery network adopted in this example embodiment will be described below.

The substrate 101 may include a semiconductor, e.g., Si or Ge, or a compound semiconductor, e.g., SiGe, SiC, GaAs, InAs, or InP. In another example embodiment, the substrate 101 may have a silicon on insulator (SOI) structure. The active region 102 may be a conductive region, e.g., a well doped with impurities or a structure doped with impurities. For example, the active region 102 may be an N-type well for a P-MOS transistor or a P-type well for an N-MOS transistor.

An element isolation layer 130 may define the active region 102 including the fin-type active pattern 105. A portion of the fin-type active pattern 105 may protrude from an upper surface of the element isolation layer 130. For example, the element isolation layer 130 may include a silicon oxide or silicon oxide-based insulating material. The element isolation layer 130 may be divided into a first element isolation layer 130a defining the active region 102 except for the fin-type active pattern 105, and a second element isolation layer 130b defining the fin-type active pattern 105. The first element isolation layer 130a may have a bottom surface deeper than that of the second element isolation layer 130b, e.g., the bottom surface of the first element isolation layer 130a may be closer to the substrate 101 than the bottom surface of the second element isolation layer 130b is. For example, the first element isolation layer 130a may be referred to as deep trench isolation (DTI), and the second element isolation layer 130b may be referred to as shallow trench isolation (STI).

Referring to FIG. 1, the fin-type active pattern 105 may extend (e.g., lengthwise) from an upper surface of the active region 102 in the first direction (e.g., the X-direction). The fin-type active pattern 105 has a structure protruding upward (e.g., a Z-direction) from the upper surface of the active region 102, as illustrated in FIG. 2. On the fin-type active pattern 105, a plurality of semiconductor patterns SP may be spaced apart from each other in a third direction (e.g., the Z-direction), perpendicular to an upper surface of the substrate 101 (FIG. 2). The fin-type active pattern 105 and the plurality of semiconductor patterns SP may be provided to a multi-channel layer of a transistor. In this example embodiment, two semiconductor patterns SP are illustrated, but the number thereof may be any suitable number, e.g., three or more. For example, the semiconductor patterns SP may include at least one of, e.g., silicon (Si), silicon germanium (SiGe), and germanium (Ge).

The semiconductor device 100 according to an example embodiment may include a line-shaped gate structure GS extending (e.g., lengthwise) in the second direction (e.g., the Y-direction), as illustrated in FIG. 1. The gate structure GS may be disposed in one region of the fin-type active pattern 105, e.g., the gate structures GS may intersect the fin-type active patterns 105 (FIG. 1).

As illustrated in FIG. 2, the gate structure GS may include gate spacers 141, a gate insulating film 142, gate electrodes 145 sequentially disposed between the gate spacers 141, and a gate capping layer 147 disposed on the gate electrodes 145. For example, the gate spacers 141 may include an insulating material, e.g., silicon nitride (SiN), silicon oxynitride (SiON), silicon carbonitride (SiCN) or silicon oxycarbonitride (SiOCN). The gate insulating film 142 may be formed of, e.g., a silicon oxide film, a high dielectric film, or combinations thereof. The high dielectric film may include a material having a higher dielectric constant (e.g., about 10 to 25) than the silicon oxide film. For example, the high dielectric film may include a material selected from, e.g., hafnium oxide, hafnium oxynitride, hafnium silicon oxide, lanthanum oxide, lanthanum aluminum oxide, and combinations thereof. The gate electrode 145 may include a conductive material, e.g., a metal nitride such as a titanium nitride film (TiN), a tantalum nitride film (TaN), or a tungsten nitride film (WN), and/or a metal material such as aluminum (Al), tungsten (W), or molybdenum (Mo), or a semiconductor material such as a doped polysilicon. In some example embodiments, the gate electrode 145 may be a multilayer including two or more films. Furthermore, the gate capping layer 147 may include, e.g., silicon nitride, silicon oxynitride, silicon carbonitride, or silicon oxycarbonitride.

The source/drain region 110 may be disposed on a region of the fin-type active pattern 105 disposed on both sides (e.g., opposite sides) of the gate structure GS. The source/drain region 110 may be connected to both ends (e.g., opposite ends) of a plurality of semiconductor patterns SP in the first direction (e.g., the X-direction). The gate electrode 145 may extend (e.g., lengthwise) in the second direction (e.g., Y-direction) to intersect the fin-type active pattern 105 while surrounding the plurality of semiconductor patterns SP. The gate electrode 145 may be interposed not only between the gate spacers 141 but also between the plurality of semiconductor patterns SP.

Inner spacers IS provided between each of the source/drain regions 110 and the gate electrode 145 may be included. The inner spacers IS are provided on both sides of the gate electrode 145, e.g., the inner spacers IS may be provided on opposite sides of each of the portions of the gate electrode 145 interposed between the plurality of semiconductor patterns SP in the first direction (e.g., the X-direction). The plurality of semiconductor patterns SP are connected to the source/drain regions 110 on both sides thereof, and a portion of the gate electrode 145 disposed between the plurality of semiconductor patterns SP may be electrically insulated from source/drain regions 110 on both sides thereof by the inner spacers IS. The gate insulating film 142 may be disposed between the gate electrode 145 and each of the semiconductor patterns SP, and may also extend between the gate electrode 145 and the inner spacers IS. As described above, the semiconductor device 100 according to this example embodiment may form a gate-all-around type field effect transistor.

The source/drain region 110 may include an epitaxial pattern formed with selective epitaxial growth (SEG) using a recessed surface of the fin-type active pattern 105 (including side surface of the plurality of semiconductor patterns SP) as a seed on both sides of the gate structure GS. The source/drain region 110 is also referred to as a raised source/drain (RSD). For example, the source/drain region 110 may be Si, SiGe, or Ge, and may have either an N-type or P-type conductivity. For example, when forming a P-type source/drain region 110, the source/drain region 110 grows back to SiGe, and a P-type impurity, e.g., one of boron (B), indium (In), gallium (Ga), and boron trifluoride (BF₃), may be doped therein. In another example, when forming silicon (Si) in an N-type source/drain region 110, an N-type impurity, e.g., one of phosphorus (P), nitrogen (N), arsenic (As), and antimony (Sb), may be doped therein. The source/drain region 110 may have different shapes along its crystallographically stable side during a growth process. For example, as illustrated in FIG. 2, the source/drain region 110 may have a pentagonal cross-section (e.g., in the case of a P-type), but may have a hexagonal cross-section or a polygonal cross-section having gentle angles (e.g., in the case of an N-type).

The semiconductor device 100 according to an example embodiment may include an interlayer insulating layer 160 disposed on the element isolation layer 130. The interlayer insulating layer 160 may be disposed around the gate structure GS while partially covering the source/drain region 110. For example, the interlayer insulating layer 160 may be flowable oxide (FOX), Tonen SilaZen (TOSZ), undoped silica glass (USG), Borosilica glass (BSG), PhosphoSilica glass (PSG), BoroPhosphoSilica glass (BPSG), plasma enhanced tetra ethyl ortho silicate (PETEOS), fluoride silicate glass (FSG), high density plasma (HDP) oxide, plasma enhanced oxide (PEOX), flowable CVD (FCVD) oxide, or combinations thereof. The interlayer insulating layer 160 may be formed using, e.g., chemical vapor deposition (CVD), a flowable-CVD process, or a spin coating process. For example, the interlayer insulating layer 160 and the element isolation layer 130 may be integral with each other, e.g., formed simultaneously as a single and seamless layer. In the present specification, the term “interlayer insulating unit” refers to an insulating part including both the interlayer insulating layer 160 and the element isolation layer 130.

A contact structure 180 may pass through the interlayer insulating layer 160 and may be connected to the source/drain region 110. The contact structure 180 may interconnect the source/drain region 110 and the first wiring structure 190. The contact structure 180 may include a conductive barrier 182 and a contact plug 185.

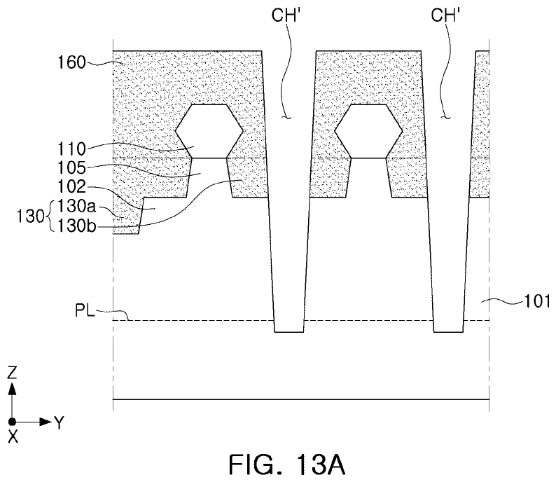

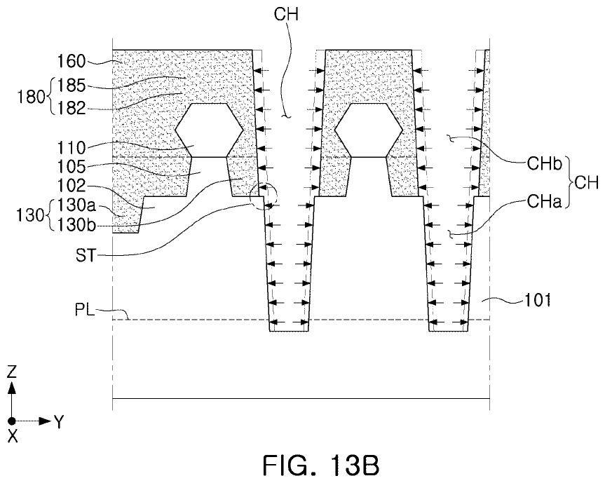

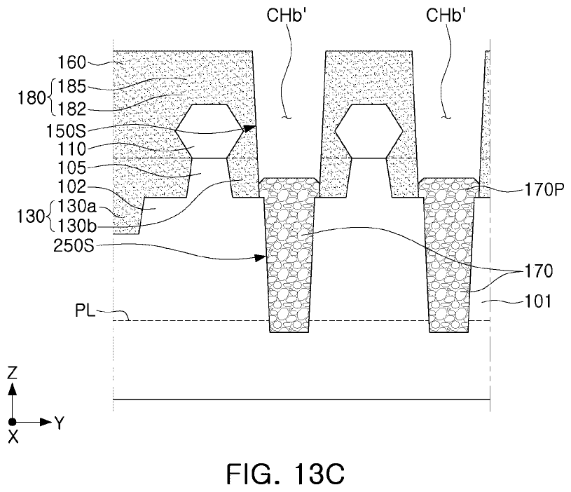

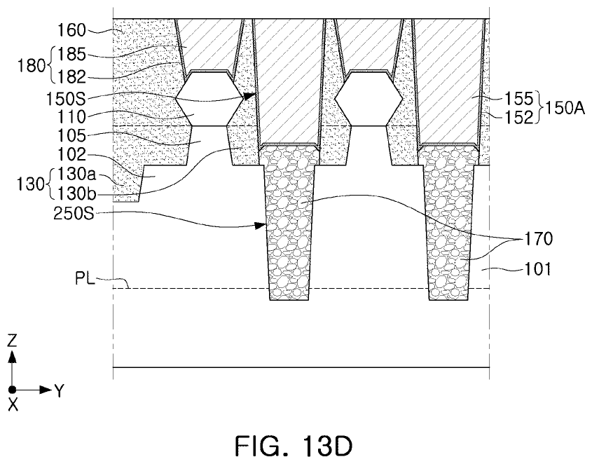

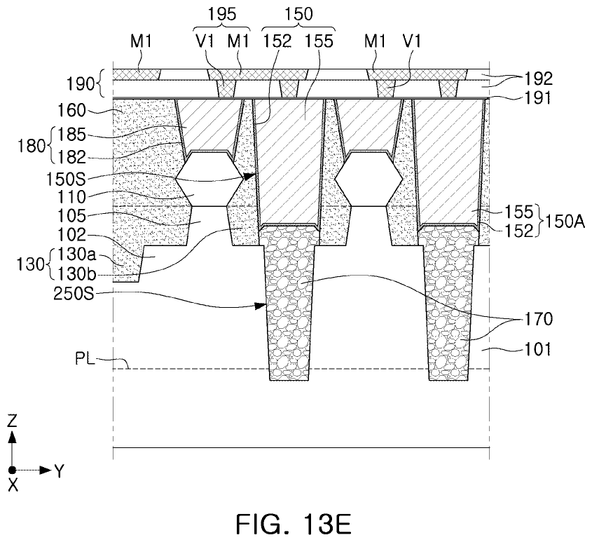

A power transmission in an example embodiment includes the buried conductive structure 150 electrically connected to the source/drain region 110 in the interlayer insulating layer 160 and the element isolation layer 130, the conductive through structure 250 connected to the buried conductive structure 150 by penetrating the substrate 101 from the second surface of the substrate 101, and the power transmission line 270 disposed on the second surface of the substrate 101 and connected to the conductive through structure 250. In this example embodiment, the buried conductive structure 150 and the conductive through structure 250 may be formed using a single hole penetrating through the interlayer insulating layer 160, the element isolation layer 130, and the substrate 101 (see FIG. 13A).

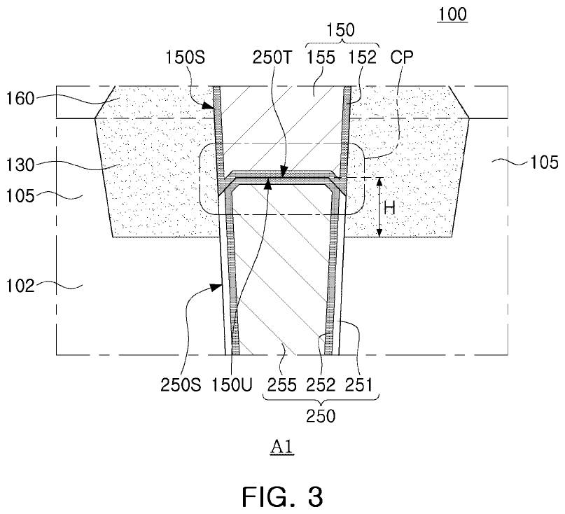

FIG. 3 is a partial enlarged view illustrating region “A1” of the semiconductor device illustrated in FIG. 2.

Referring to FIGS. 2 and 3, the buried conductive structure 150 may be buried in the interlayer insulating layer 160 and the element isolation layer 130, and may extend in a direction (e.g., in the Z-direction), perpendicular to the first surface of the substrate 101. For example, referring to FIGS. 1 and 2, a perimeter of the buried conductive structure 150 may be completely surrounded by the combined structure of the interlayer insulating layer 160 and the element isolation layer 130, as viewed in a top view.

As further illustrated in FIGS. 2 and 3, in an example embodiment, the conductive through structure 250 may be connected to the buried conductive structure 150 in the element isolation layer 130, and may penetrate through the substrate 101 on the second surface of the substrate 101, e.g., may penetrate through the entire substrate 101 and the second surface of the substrate 101 facing away from the buried conductive structure 150. As illustrated in FIG. 3, an upper surface 250T of the conductive through structure 250 may be in contact with a bottom surface 150U of the buried conductive structure 150 in a region higher than the first surface of the substrate 101, e.g., relative to the second surface of the substrate 101. In some example embodiments, an upper surface level of the conductive through structure 250, i.e., a contact level, may have a lower level than that of a lower surface of the source/drain region 110 (i.e., dashed line in FIG. 3). For example, a height H of the upper surface of the conductive through structure 250 from the first surface of the substrate 101, e.g., from an upper surface of the active region 102, may be less than 100 μm (e.g., 50 μm).

The conductive through structure 250 may have a first width W1 adjacent to the first surface of the substrate 101 (e.g., adjacent to the upper surface of the active region 102), and a second width W2 adjacent to the second surface of the substrate 101 (e.g., adjacent to the power transmission line 270). In this example embodiment, the conductive through structure 250 may have a width that gradually narrows as it approaches the second surface of the substrate 101. Similarly to the conductive through structure 250, the buried conductive structure 150 may have a width that gradually decreases as it approaches the second surface of the substrate 101.

As illustrated in FIG. 3, a contact portion CP, in which the buried conductive structure 150 and the conductive through structure 250 are in contact with each other, may have a continuous side surface, e.g., completely flat side surface. Here, the continuous side surface refers to a side surface that is connected without a substantial step portion when two distinct structures 150 and 250 are connected to each other. As described above, the continuous side surface may be understood as having a structure obtained because the buried conductive structure 150 and the conductive through structure 250 are formed in one hole (e.g., “CH” of FIG. 13A) which is previously prepared. In this example embodiment, not only the contact portion CP, but also a side surface 150S of the buried conductive structure 150 and a side surface 250S of the conductive through structure 250 may form continuous side surfaces as a whole, e.g., the entire side surface 150S of the buried conductive structure 150 and the entire side surface 250S of the conductive through structure 250 may be level with each other to form a flat surface. For example, the entire side surfaces of the contact portion CP, the buried conductive structure 150, and the conductive through structure 250 may be flat and level with each other to define a surface without step portions. The overall continuous side surfaces 150S and 250S of the two structures 150 and 250 may be understood as having a structure obtained by not introducing an etching process (see FIG. 13B) for hole expansion after forming a hole (see FIG. 13A), or by significantly reducing an etching rate difference between the interlayer insulating unit (e.g., the interlayer insulating layer 160 and the element isolation layer 130) and the substrate 101, even when the etching process is introduced.

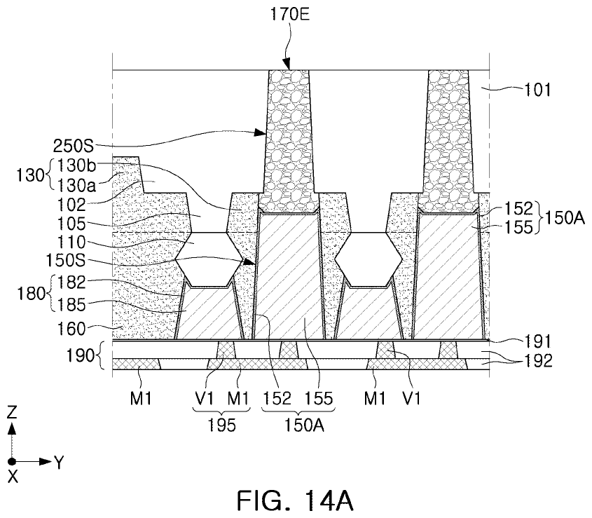

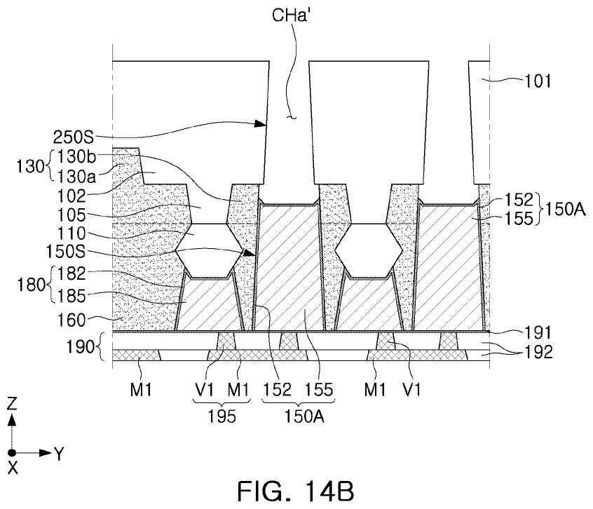

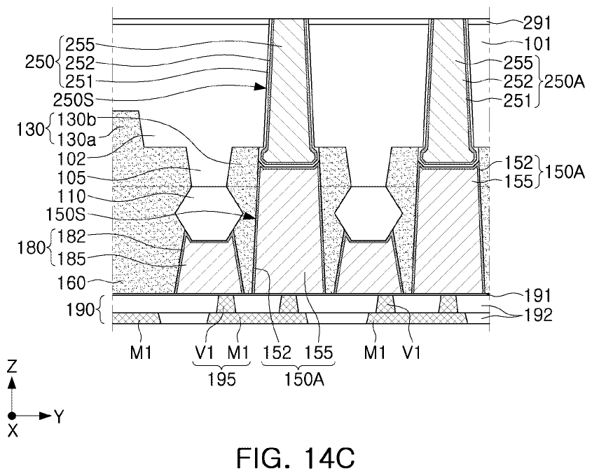

The upper surface 250T of the conductive through structure 250 may have a curved, e.g., a convex, shape. The bottom surface 150U of the buried conductive structure 150 in contact with the upper surface 250T of the conductive through structure 250 may have a concave shape corresponding to the convex shape, e.g., the bottom surface 150U and the upper surface 250T may have complementary shapes. When a sacrificial material layer defining a formation region of the conductive through structure 250 is charged (see FIG. 13C), the convex upper surface 250T of the conductive through structure 250 may be determined by a shape of the upper surface of the sacrificial material layer. For example, when the sacrificial material layer is a semiconductor single crystal, e.g., SiGe, the sacrificial material layer may have a convex crystal surface composed of a stable crystal plane. In some example embodiments, a shape of the crystal plane may be slightly changed in subsequent processes (e.g., see FIG. 14B), so that the convex upper surface 250T of the conductive through structure 250 may have a somewhat smoother shape than that of the convex crystal surface.

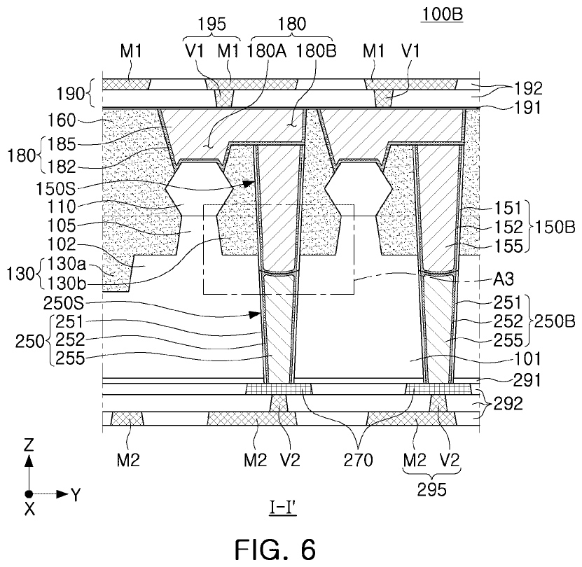

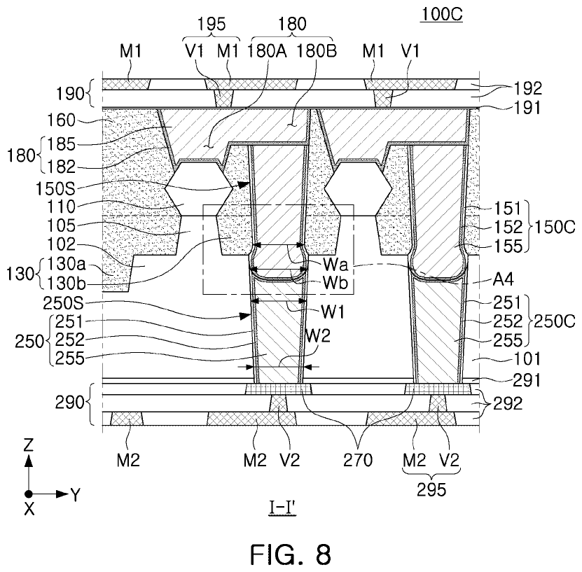

In an example embodiment, the buried conductive structure 150 may be connected to the contact structure 180 through the first wiring structure 190. In this manner, the power transmitted through the power transmission structure in this example embodiment may be supplied to a desired region (e.g., the source/drain region 110) through the first wiring structure 190. An electrical connection between the buried conductive structure 150 and the source/drain region 110 may be implemented in various forms. For example, the buried conductive structure 150 may be directly connected to the contact structure 180 (see FIGS. 6 and 8).

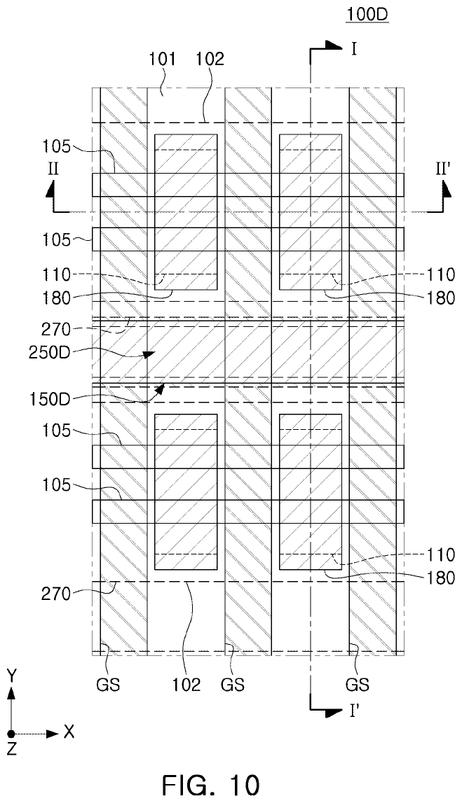

In an example embodiment, the buried conductive structure 150 and the conductive through structure 250 may each include a via structure, e.g., a column shape (see FIG. 1). The present disclosure is not limited thereto, e.g., a conductive through structure 250C may have a rail shape extending in the first direction (e.g., the X-direction) (see FIG. 10).

The buried conductive structure 150 may include a first contact plug 155 and a first conductive barrier 152 in which a side surface and a bottom surface of the first contact plug 155 are disposed. In some example embodiments, the buried conductive structure 150 may further include a first insulating liner disposed on a portion of the first conductive barrier 152 surrounding a side surface of the first contact plug 155.

The conductive through structure 250 may include a second contact plug 255 connected to the buried conductive structure 150 by penetrating through the substrate 101, a second conductive barrier 252 disposed on a side surface and an upper surface of the second contact plug 255, and a second insulating liner 251 disposed between the second conductive barrier 252 and the substrate 101.

For example, at least one of the first conductive barrier 152 and the second conductive barrier 252 may include Ta, TaN, Mn, MnN, WN, Ti, TiN, or combinations thereof. In an example embodiment, the first conductive barrier 152 and the second conductive barrier 252 may include different conductive materials. In some example embodiments, the first conductive barrier 152 may include TiN, and the second conductive barrier 252 may include TaN or Co/TaN.

For example, at least one of the first contact plug 155 and the second contact plug 255 may include Cu, Co, Mo, Ru, W, or alloys thereof. In an example embodiment, the first contact plug 155 and the second contact plug 255 may include different conductive materials. In some example embodiments, the first contact plug 155 may include Mo, and the second contact plug 255 may include Cu or W.

For example, at least one of the first insulating liner and the second insulating liner 251 may include, e.g., SiO₂, SIN, SiCN, SiC, SiCOH, SiON, Al₂O₃, AlN, or combinations thereof.

As illustrated in FIG. 2, the contact structure 180 may be connected to the first wiring structure 190 forming the back end of lines (BEOL). The first wiring structure 190 may be configured to connect a plurality of elements (e.g., transistors including the source/drain region 110 and the gate electrode 145) implemented in the first surface of the substrate 101, i.e., the active region 102.

The first wiring structure 190 may include a plurality of first insulating layers 192 and a first wiring layer 195 disposed on the plurality of first insulating layers 192. The first wiring layer 195 may include a metal wiring M1 and a metal via V1. The metal wiring M1 may be disposed on the first insulating layer 192, and the metal via V1 may penetrate through the first insulating layer 192. Here, the metal via V1 may be connected to the contact structure 180 (see FIG. 2).

For example, the first insulating layer 192 may include silicon oxide, silicon nitride, SiOC, SiCOH, or combinations thereof. For example, the metal wiring M1 and the metal via V1 may include copper or a copper-containing alloy. In some example embodiments, the metal wiring M1 and the metal via V1 may be formed together using a dual-damascene process.

As in this example embodiment, an etching stop layer 191 disposed between the interlayer insulating layer 160 and the first insulating layer 192 may be further included. The etching stop layer 191 may not only serve as an etch stop, but may also prevent metals (e.g., Cu) constituting the metal wire M1 and the metal via V1 from diffusing to a lower region. For example, the etching stop layer 191 may include aluminum nitride (AlN).

In an example embodiment, the power transmission line 270 connected to the conductive through structure 250 and the second wiring structure 290 connected to the power transmission line 270 may be disposed on the second surface of the substrate 101.

The power transmission line 270 may have a rail structure extending in one direction. For example, as illustrated in FIG. 1, power transmission lines 270 may extend in the first direction (X-direction) and may be spaced apart from each other in the second direction (Y-direction).

A second etching stop layer 291 may be disposed on the second surface of the substrate 101, and the second wiring structure 290 connected to the conductive through structure 250 may be disposed on the second etching stop layer 291. Similarly to the first wiring structure 190, the second wiring structure 290 may include a plurality of second insulating layers 292 and a second wiring layer 295 disposed on the plurality of second insulating layers 292. Similarly to the first wiring layer 195, the second wiring layer 295 may include a metal wiring M2 and a metal via V2. Here, the metal via V2 may be connected to the power transmission line 270 (see FIG. 2).

In an example embodiment, the second wiring layer 295 of the second wiring structure 290 may include a wiring layer for power transmission, and the first wiring layer 195 of the first wiring structure 190 may include a wiring layer for signal transmission. Power may be transmitted from the second wiring structure 290 (especially, the power transmission line 270) disposed on the second surface of the substrate 101 to the first wiring layer 195 through the conductive through structure 250 and the buried conductive structure 150, and may be supplied to a desired element region (e.g., the source/drain region 110) through the first wiring layer 195.

As described above, because the conductive through structure 250 implemented in this example embodiment is formed using a single hole structure along with the buried conductive structure 150, it may be self-aligned with the buried conductive structure 150 with little alignment errors. Furthermore, through such precise self-alignment, the buried conductive structure 150 and the conductive through structure 250 may be arranged to have continuous side surfaces, thereby stably securing sufficient contact area by preventing a decrease in contact area due to misalignment.

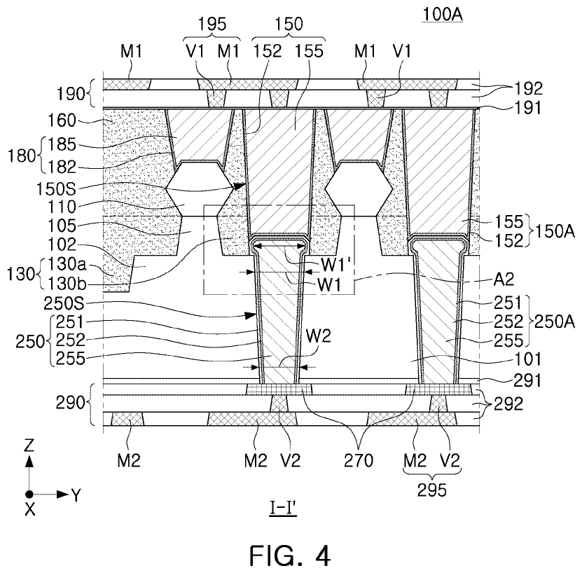

The shape and connection position of the conductive through structure and the buried conductive structure according to an example embodiment may be variously changed. In some example embodiments, after forming a single hole for the conductive through structure and the buried conductive structure, an etching process (see FIG. 13B) may be additionally performed to expand in a width direction. In this case, the conductive through structure and the buried conductive structure may be variously changed according to the etching condition (FIGS. 4 and 5, and FIGS. 8 and 9). In some example embodiments, a contact position of the conductive through structure and the buried conductive structure may vary depending on an upper surface level (see FIG. 13C) of the sacrificial material layer after hole formation (see FIGS. 4 and 5, FIGS. 6 and 7, and FIGS. 8 and 9).

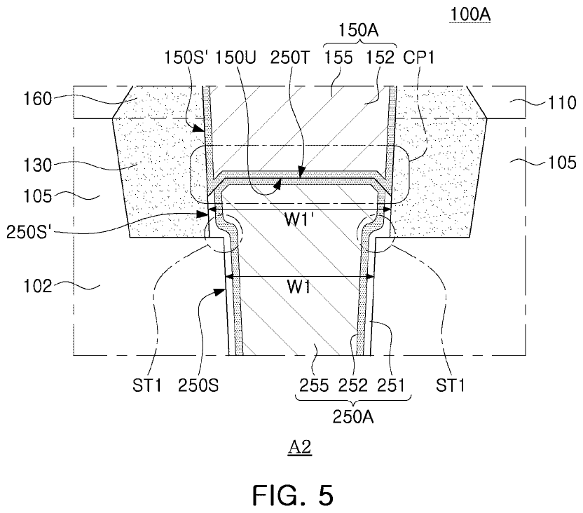

FIG. 4 is a cross-sectional view illustrating a semiconductor device according to an example embodiment of the present disclosure, and FIG. 5 is an enlarged cross-sectional view illustrating region “A2” of the semiconductor device illustrated in FIG. 4.

Referring to FIGS. 4 and 5, a semiconductor device 100A according to an example embodiment may be understood as having a structure similar to the semiconductor device 100 illustrated in FIGS. 1 to 3, except that a contact portion CP1 of a buried conductive structure 150A and a conductive through structure 250A is disposed relatively low, and a side surface of the conductive through structure 250A has a step portion ST1 on the first surface of the substrate 101. Furthermore, components of this example embodiment may be understood by referring to the description of the same or similar components of the semiconductor device 100 illustrated in FIGS. 1 to 3, unless otherwise described.

As illustrated in FIGS. 4 and 5, in an example embodiment, the contact portion CP1 of the buried conductive structure 150A and the conductive through structure 250A may be disposed on the first surface of the substrate 101 but may be disposed lower than the previous example embodiment, e.g., closer to the first surface of the substrate 101. This may be implemented by forming a single hole for the buried conductive structure 150A and the conductive through structure 250A, and then adjusting the upper surface level (see FIG. 13C) of the sacrificial material layer.

Referring to FIG. 5, the contact portion CP1 may have a continuous side surface, similarly to the previous example embodiment. In this example embodiment, the contact portion CP1 may have an external side surface on which the buried conductive structure 150A and the conductive through structure 250A are connected without a substantial step portion in the element isolation layer 130, higher than the first surface of the substrate 101. Furthermore, similarly to the previous example embodiment, the upper surface 250T of the conductive through structure 250A may have a convex shape. The bottom surface 150U of the buried conductive structure 150A in contact with the upper surface 250T of the conductive through structure 250A may have a concave shape corresponding to the convex shape.

Similarly to the previous example embodiment, the buried conductive structure 150A and the conductive through structure 250A may have a width that gradually narrows as it approaches the second surface of the substrate 101. For example, the conductive through structure 250A may have the first width W1 adjacent to the first surface of the substrate 101 and the second width W2 adjacent to the second surface of the substrate 101. However, as described in FIG. 5, the side surface of the conductive through structure 250A may have the step portion ST1 on a first surface level of the substrate 101, unlike the previous example embodiment. For example, as illustrated in FIG. 5, the conductive through structure 250A may include the step portion ST1 below the contact portion CP1, so an upper portion of the side surface of the conductive through structure 250A may be level with the side surface of the buried conductive structure 150A. The step portion ST1 may be an example of a structure caused by additional expansion in a width direction during a manufacturing process.

Specifically, the buried conductive structure 150A and the conductive through structure 250A may have a structure expanded in the width direction as compared to the buried conductive structure 150 and the conductive through structure 250 (indicated by dotted lines) of the previous example embodiment. A portion of the conductive through structure 250A disposed in the element isolation layer may have an expanded width W1′ greater than the first width W1. The expansion of the width may be obtained by a wet etching process (see FIG. 13B) performed after forming a single hole for the buried conductive structure 150A and the conductive through structure 250A (see FIG. 13A).

Each of the buried conductive structure 150A and the conductive through structure 250A may maintain a tendency to have a width that gradually decreases as it moves downward, but may have the step portion ST1 according to an etching rate condition according to a material. As in this example embodiment, when the etching rate of the interlayer insulating layer 160 and the element isolation layer 130 is higher in wet etching for expansion, because expansion widths of the interlayer insulating layer 160 and the element isolation layer 130 is greater than an expansion width of the substrate 101, the step portion ST1 may occur on the first surface level of the substrate 101. That is, as illustrated in FIG. 5, the side surface of the conductive through structure 250A may have the step portion ST1 on the first surface level of the substrate 101.

In this manner, not only may the contact portion CP1 have an accurate alignment to have a continuous side surface, but it may also exist in a region extending from the element isolation layer 130 in the width direction, thereby further expanding a contact area and further improving a contact resistance problem.

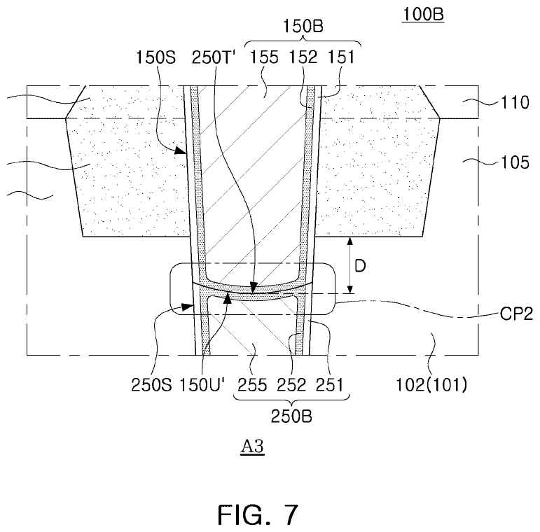

FIG. 6 is a cross-sectional view illustrating a semiconductor device according to an example embodiment of the present disclosure, and FIG. 7 is an enlarged cross-sectional view illustrating region “A3” of the semiconductor device illustrated in FIG. 6

According to FIGS. 6 and 7, a semiconductor device 100B according to an example embodiment may be understood as having a structure similar to the semiconductor device 100 illustrated in FIGS. 1 to 3, except that a contact portion CP2 of a buried conductive structure 150B and a conductive through structure 250B is disposed in the substrate 101, an upper surface 250T′ of the conductive through structure 250B has a concave surface, and the buried conductive structure 150B is connected to the contact structure 180. Furthermore, components of this example embodiment may be understood by referring to the description of the same or similar components of the semiconductor device 100 illustrated in FIGS. 1 to 3, unless otherwise described.

In an example embodiment, the contact portion CP2 of the buried conductive structure 150B and the conductive through structure 250B is disposed lower than the first surface of the substrate 101, i.e., inside the substrate 101. A position of the contact portion CP2 may be implemented by forming a single hole for the buried conductive structure 150B and the conductive through structure 250B, and then forming the sacrificial material layer lower than the first surface of the substrate 101. In some example embodiments, an upper surface of the conductive through structure 250B, i.e., a contact level, may be disposed at a depth D from the first surface of the substrate 101, e.g., at a depth of 200 μm or 100 μm below the first surface of the substrate 101.

Similarly to the previous example embodiment, the contact portion CP2 may have an external side surface on which the buried conductive structure 150B and the conductive through structure 250B are connected without a substantial step portion in the substrate 101.

The upper surface 250T′ of the conductive through structure 250B in this example embodiment may have a concave shape, unlike the previous example embodiment. Such a concave shape may be obtained according to an upper shape of a sacrificial material layer 170 (see FIG. 13C) partially filled in a single hole. A bottom surface 150U′ of the buried conductive structure 150B in contact with the upper surface 250T′ of the conductive through structure 250B may have a convex shape corresponding to the concave shape.

The contact structure 180 in this example embodiment may be configured to be directly connected to the buried conductive structure 150B. Referring to FIG. 6, the contact structure 180 may include a first contact portion 180A connected to the source/drain region 110 and a second contact portion 180B extending to be connected to the buried conductive structure 150B. The second contact portion 180B may extend from the first contact portion 180A in the second direction (e.g., in the Y-direction) to be easily connected to the buried conductive structure 150B.

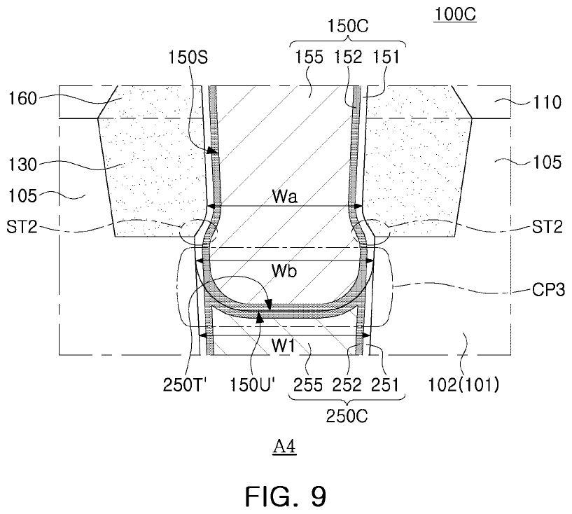

FIG. 8 is a cross-sectional view illustrating a semiconductor device according to an example embodiment of the present disclosure, and FIG. 9 is an enlarged cross-sectional view illustrating region “A4” of the semiconductor device illustrated in FIG. 8.

Referring to FIGS. 8 and 9, a semiconductor device 100C according to an example embodiment may be understood as having a structure similar to the semiconductor device 100 illustrated in FIGS. 1 to 3, except that a contact portion CP3 of a buried conductive structure 150C and a conductive through structure 250C is disposed in the substrate 101, a side surface of the buried conductive structure 150C has a step portion SP2 on the first surface of the substrate 101, and the buried conductive structure 150C is connected to the contact structure 180. Furthermore, components of this example embodiment may be understood by referring to the description of the same or similar components of the semiconductor device 100 illustrated in FIGS. 1 to 3, unless otherwise described.

Referring to FIG. 8, the contact portion CP3 of the buried conductive structure 150C and the conductive through structure 250C is disposed in the substrate 101, similarly to the example embodiment illustrated in FIG. 6. Similarly to the previous example embodiment, the contact portion CP3 may have an external side surface on which the buried conductive structure 150C and the conductive through structure 250C are connected without a substantial step portion in the substrate 101, e.g., portions of side surfaces of the buried conductive structure 150C and the conductive through structure 250C within the contact portion CP3 (within the substrate 101) may be level with each other.

Similarly to the previous example embodiments, the conductive through structure 250C may have a width that gradually narrows as it approaches the second surface of the substrate 101. In this example embodiment, an upper region of the buried conductive structure 150C, i.e., a region disposed in the interlayer insulating layer and the element isolation layer, has a width that generally narrows as it approaches the second surface of the substrate 101, but as illustrated in FIG. 9, a side surface of the buried conductive structure 150C may have the step portion ST2 on the first surface level of the substrate 101. The step portion ST2 may be an example of a structure caused by additional expansion in the width direction during the manufacturing process. Specifically, the buried conductive structure 150C and the conductive through structure 250C may have a structure expanded in the width direction as compared to the buried conductive structure 150B and the conductive through structure 250B of the previous example embodiment. The extension of the width may be obtained by a wet etching process performed after forming a single hole for the buried conductive structure 150C and the conductive through structure 250C.

In an example embodiment, when an etching rate of the substrate 101 in the wet etching for expansion is higher than etching rates of the interlayer insulating layer 160 and the element isolation layer 130, because an expanded width of the substrate 101 is greater than extended widths of the interlayer insulating layer 160 and the element isolation layer 130, the step portion ST2 may occur on the first surface level of the substrate 101. In other words, as illustrated in FIG. 9, the buried conductive structure 150C may have the step portion ST2 on the first surface level of the substrate 101, e.g., completely above the substrate 101. The buried conductive structure 150C may have a portion disposed in the substrate 101 having a width Wb greater than a width Wa of a portion disposed in the element isolation layer 130.

In this manner, not only may the contact portion CP3 have an accurate alignment to have a continuous side surface, but it may also exist in a region extending from the element isolation layer 130 in the width direction, thereby further expanding a contact area and further improving a contact resistance problem.

The upper surface 250T′ of the conductive through structure 250C in this example embodiment may have a concave shape. The bottom surface 150U′ of the buried conductive structure 150C in contact with the upper surface 250T′ of the conductive through structure 250C may have a convex shape corresponding to the concave shape.

The contact structure 180 implemented in this example embodiment may be configured to be directly connected to the buried conductive structure 150C. Referring to FIG. 8, the contact structure 180 may include the first contact portion 180A connected to the source/drain region 110 and the second contact portion 180B extending to be connected to the buried conductive structure 150C. The second contact portion 180B may extend from the first contact portion 180A in the second direction (e.g., in the Y-direction) to be easily connected to the buried conductive structure 150C.

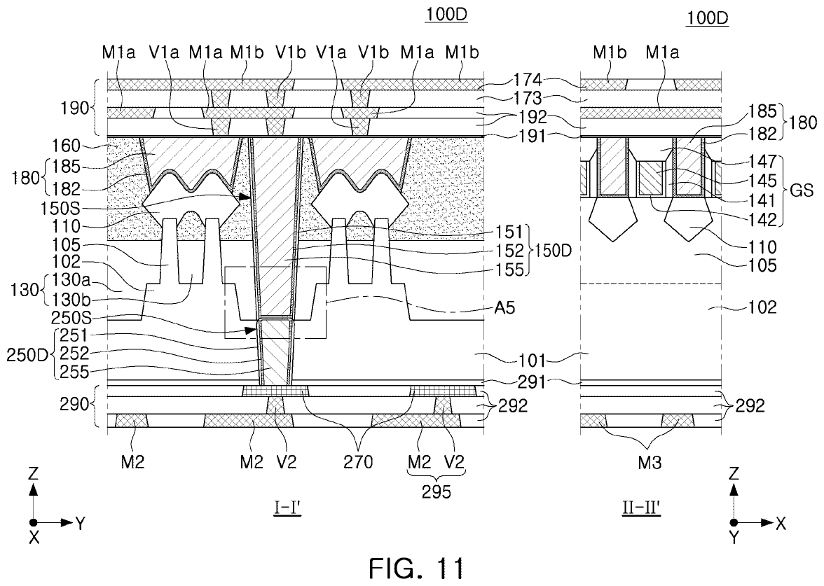

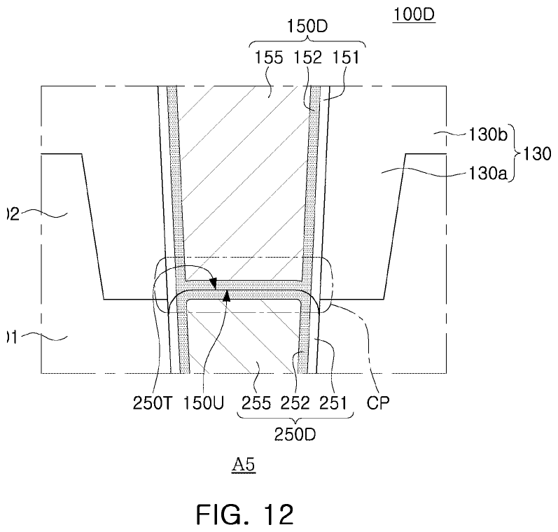

FIG. 10 is a plan view illustrating a semiconductor device according to an example embodiment of the present disclosure, and FIG. 11 is cross-sectional views taken along line I-I′ and line II-II′ of the semiconductor device illustrated in FIG. 10. FIG. 12 is an enlarged cross-sectional view of region “A5” in FIG. 11. Here, for convenience, the first and second wiring structures 190 and 290 are not illustrated in FIG. 10.

Referring to FIGS. 10 and 11, a semiconductor device 100D according to an example embodiment may be understood as having a structure similar to the semiconductor device 100 illustrated in FIGS. 1 to 3, except that a channel region is provided as two fin-type active patterns 105, a buried conductive structure 150D and a conductive through structure 250D extend in the first direction (e.g., the X-direction), the buried conductive structure 150D is disposed in a first element isolation layer 130a between active regions 102, and a contact portion CP of the buried conductive structure 150D and the conductive through structure 250D is disposed on almost the same level as the first surface of the substrate 101. Furthermore, components of this example embodiment can be understood by referring to the description of the same or similar components of the semiconductor device 100 illustrated in FIGS. 1 to 3, unless otherwise described.

The channel region in the present example embodiment may include the fin-type active patterns 105 provided in a 3D channel structure, unlike the previous example embodiment. Each of the fin-type active patterns 105 may protrude upward (e.g., in the Z-direction) from an upper (i.e., first) surface of the substrate 101 (i.e., from the upper surface of the active region 102), and may extend in the first direction (e.g., in the X-direction).

As illustrated in FIGS. 10 and 11, the fin-type active patterns 105 may be arranged side by side in the second direction (e.g., Y-direction) in the active region 102. In this example embodiment, the two fin-type active patterns 105 arranged adjacent to each other provide a channel region for one transistor. In this example embodiment, the fin-type active patterns 105 are illustrated as being provided by two, but the present disclosure not limited thereto, e.g., the fin-type active pattern 105 may be provided in single or plural form (e.g., three or more).

The semiconductor device 100D according to an example embodiment may include a source/drain region 110 formed over the two fin-type active patterns 105 and a contact structure 180 connected to the source/drain region 110.

The gate structure GS employed in this example embodiment may overlap one region of each of the fin-type active pattern 105. The gate structure GS may include the gate spacers 141, the gate insulating film 142 and the gate electrode 145 sequentially disposed between the gate spacers 141, and the gate capping layer 147 disposed on the gate electrode 145.

In this example embodiment, the buried conductive structure 150D may be electrically connected to the contact structure 180 through the first wiring structure 190. The first wiring structure 190 may be connected to an upper surface of the contact structure 180 through one metal via V1, and may be connected to the buried conductive structure 150D through another metal via V1.

As illustrated in FIGS. 11 and 12, the buried conductive structure 150D may be formed in a region in which the first element isolation layer 130a is disposed. The buried conductive structure 150D may be formed over, e.g., through, the first element isolation layer 130a as well as the second element isolation layer 130b, and a bottom surface of the buried conductive structure 150D may be disposed in a region adjacent to the first surface of the substrate 101. The conductive through structure 250D may extend from the second surface of the substrate 101 to the region adjacent to the first surface of the substrate 101 and may be connected to the buried conductive structure 150D in the region adjacent to the first surface of the substrate 101.

The buried conductive structure 150D and the conductive through structure 250D in this example embodiment may be rail structures formed by a trench extending in one direction, not hole-shaped via structures. As illustrated in FIG. 10, the buried conductive structure 150D and the conductive through structure 250D may have a rail structure extending in the first direction (e.g., the X-direction). An extended length may be variously selected as needed.

In this example embodiment, the upper surface 250T of the conductive through structure 250D may have a convex portion. The bottom surface 150U of the buried conductive structure 150D in contact with the upper surface 250T of the conductive through structure 250D may have a concave shape corresponding to the convex portion.

As illustrated in FIG. 12, the convex portion of the conductive through structure 250D may horizontally overlap the first surface of the substrate 101. The contact portion in this example embodiment has a continuous side surface similarly to the previous example embodiments, but when a hole expansion process is applied, the contact portion disposed on the first surface level of the substrate 101 may have a step portion instead of the continuous side surface (e.g., as in FIG. 4).

In this example embodiment, the conductive through structure 250D is illustrated in a form having a convex portion (or a convex contact surface), but similarly to the example embodiments of FIGS. 7 and 9, the conductive through structure 250D may be disposed to horizontally overlap the first surface of the substrate 101.

FIGS. 13A to 13E are cross-sectional views of stages (e.g., processes of forming a buried conductive structure and a first wiring structure) in a method of manufacturing the semiconductor device illustrated in FIG. 4, and FIGS. 14A to 14C are cross-sectional views of other stages (e.g., processes of forming a conductive through structure) in the method of manufacturing the semiconductor device illustrated in FIG. 4.

Referring to FIG. 13A, a hole CH′ extending to an interior of the substrate 101 may be formed by penetrating through the element isolation layer 130 and the interlayer insulating layer 160 (hereinafter referred to together as an “interlayer insulating unit”) in order to form a power transmission structure.

The substrate 101 in an example embodiment may include a gate-all-around type field effect transistor, similarly to the semiconductor device 100A illustrated in FIG. 4. Specifically, referring to FIG. 4 along with FIG. 13A, these transistors may include the fin-type active pattern 105 formed on the substrate 101, the semiconductor patterns SP stacked on the fin-type active pattern 105 and spaced apart from each other, the gate structure GS intersecting the fin-type active pattern 105, and the source/drain regions 110 disposed on the fin-type active pattern 105 on both sides of the gate structure GS and connected to both side surfaces of the semiconductor patterns SP. The “interlayer insulating unit” includes the element isolation layer 130 disposed on the first surface of the substrate 101 and the interlayer insulating layer 160 disposed on the element isolation layer 130.

In this process, the hole CH′ extending to the interior of the substrate 101 is formed while penetrating through the element isolation layer 130 and the interlayer insulating layer 160. The hole CH′ may be provided as a hole structure for a buried conductive structure and a conductive through structure. In this manner, because the buried conductive structure and the conductive through structure are formed using a same single hole structure, precise self-alignment of the buried conductive structure and the conductive through structure may be easily implemented. The hole CH′ formed in this process may be formed in the substrate 101 to a depth that may be exposed to the second surface of the substrate 101 in a subsequent process (see FIG. 14A). Because the hole CH′ has a single structure, the hole CH′ may have a width that becomes narrower as it moves from the top to the bottom.

Next, referring to FIG. 13B, a process of expanding the hole CH′ in the width direction is performed.

The hole CH expanded in the present process may be obtained by the wet etching process. As described above, widths expanded from different material layers may be different depending on a difference in the etching rate. In some example embodiments, the expansion process of the hole CH may be performed to be further expanded in a region in which the contact portion of the buried conductive structure and the conductive through structure is disposed. In this example embodiment, because the contact portion is controlled to be disposed in the element isolation layer 130, the wet etching process may be performed in a condition of performing further expansion from the element isolation layer 130.

For example, as illustrated in FIG. 13B, the expanded hole CH includes a first hole portion CHa disposed in the substrate 101 and a second hole portion CHb disposed in the element isolation layer 130 and the interlayer insulating layer 160. Because an etching rate of the interlayer insulating unit (the element isolation layer 130 and the interlayer insulating layer 160 formed integrally, e.g., of SiO₂) in the wet etching process is performed in a condition that it is greater than an etching rate of the substrate (e.g., formed of Si), the second hole portion CHb may be expanded to a width greater than an expanded width of the first hole portion CHa. As described above, by the expansion process, the hole CH may have the step portion ST on the first surface level of the substrate (i.e., between the first and second hole portions CHa and CHb).

Next, referring to FIG. 13C, the sacrificial material layer 170 is formed in the first portion CHa of the hole CH.

The sacrificial material layer 170 may grow from the bottom surface of the hole CH and may include a material that has a high etching selectivity ratio with respect to a surrounding material, e.g., with respect to the material of the substrate 101. For example, the sacrificial material layer 170 may include an insulating material or a semiconductor material, e.g., SiGe. In some example embodiments, when the substrate 101 is a silicon substrate, the sacrificial material layer may include SiGe. For example, SiGe may have a composition ratio of Ge to SiGe of 0.2:1.0 or more in order to have a sufficient etching selectivity ratio with the substrate 101. Furthermore, SiGe may easily be re-grown from a bottom surface and an internal sidewall of the hole CH formed of silicon.

In an example embodiment, the sacrificial material layer 170 may be formed to have an upper surface having a higher level than that of the first surface of the substrate 101. An upper surface level of the sacrificial material layer 170 may determine the upper surface of the conductive through structure, i.e., a level of the contact portion of the buried conductive structure and the conductive through structure. For example, unlike this example embodiment, the contact portion in a final structure may be disposed in the substrate by disposing the upper surface level of the sacrificial material layer 170 inside the substrate 101. Furthermore, an upper region 170P of the sacrificial material layer 170 may be disposed in the second hole portion CHb, i.e., to horizontally overlap a portion of the element isolation layer 130. As described above, because the hole CH has a step portion, the sacrificial material layer 170 may also have the step portion ST between the upper region 170P and the remaining other region (i.e., a portion disposed in the substrate).

In the present example embodiment, the upper region of the sacrificial material layer 170 may have a convex upper surface. When the sacrificial material layer 170 is a semiconductor crystal, e.g., SiGe, it may have a convex upper surface formed of stable crystal planes. Depending on the type and growth conditions of the sacrificial material layer 170, the sacrificial material layer 170 may have a convex upper surface or a concave surface of another shape.

Next, referring to FIG. 13D, the buried conductive structure 150A is formed in a remaining upper region CHb′ of the hole.

In the remaining upper region CHb′ of the hole, the buried conductive structure 150A may be formed on the sacrificial material layer 170. In an example embodiment, the buried conductive structure 150A may be formed by forming the first conductive barrier 152 and then filling a remaining space with the first contact plug 155. The upper surface of the buried conductive structure 150A and the upper surface of the interlayer insulating layer 160 may form a substantially flat coplanar surface by performing a planarization process, e.g., chemical mechanical polishing (CMP).

In addition to this process or through a separate process, a contact hole connected to the source/drain region 110 and the buried conductive structure 150A together may be formed in the interlayer insulating layer 160, and the conductive barrier 182 and the contact plug 185 may be sequentially formed to charge a contact hole. The upper surface of the contact structure 180 and the upper surface of the interlayer insulating layer 160 may form a substantially flat coplanar surface by performing the planarization process, e.g., CMP. The conductive barrier and plug formation process and the CMP process may be performed together with some processes of the buried conductive structure 150A.

Next, referring to FIG. 13E, the first wiring structure 190 may be formed on the interlayer insulating layer 160.

The first wiring structure 190 may include the first wiring layer 195 connected to the contact structure 180 and the buried conductive structure 150A. As described above, in this example embodiment, the contact structure 180 and the buried conductive structure 150A may be connected through the first wiring layer 195. The first wiring layer 195 may include the metal wiring M1 and the metal via V1. The metal wiring M1 and the metal via V1 may be formed together by using a dual damascene process.

FIGS. 14A to 14C are cross-sectional views for stages of some other processes of the method of manufacturing the semiconductor device illustrated in FIG. 4.

Referring to FIG. 14A, in order to reduce a thickness of the substrate 101, a grinding process may be performed on the second surface of the substrate 101. For example, the grinding process may be performed up to a portion indicated by “PL” in FIG. 13E.

FIG. 14A illustrates a state in which the second surface of the substrate 101 is inverted to face upward after the grinding process of the structure illustrated in FIG. 13E. Through such a process, the sacrificial material layer 170 may be exposed from a polished second surface of the substrate 101.

Next, referring to FIG. 14B, the sacrificial material layer 170 may be removed through an exposed surface 170E of the sacrificial material layer 170.

As described above, because the sacrificial material layer 170 is formed of a material (e.g., SiGe) with a high etching selectivity ratio with respect to the substrate 101, it may be selectively removed from the substrate 101, e.g., via etching. As described above, by removing the sacrificial material layer 170, a hole region CHa′ may be formed in the substrate 101. The bottom surface of the buried conductive structure 150A may be exposed to a bottom surface of the hole region CHa′. The hole region CHa′ may be a partial region of the hole CH obtained in the process of FIG. 13B. The hole region CHa′ in the substrate 101 may be provided as a region for forming a conductive through structure.

Next, referring to FIG. 14C, the hole region CHa′ in the substrate 101 may be filled to form the conductive through structure 250A on the buried conductive structure 150A. In this manner, because the conductive through structure 250A is formed along with the buried conductive structure 150A using a same single hole prepared in advance, contact surfaces may be accurately self-aligned. In some example embodiments, the conductive through structure 250A and the buried conductive structure 150A may have continuous side surfaces at least in the contact portion.

The semiconductor device 100A illustrated in FIG. 4 may be manufactured by forming the power transmission line 270 and the second wiring structure 290 connected to the conductive through structure 250A on the second surface of the substrate 101.

In this manner, the buried conductive structure 150A and the conductive through structure 250A may be formed using the single hole CH structure and the sacrificial material layer 170, thus allowing the buried conductive structure 150A and the conductive through structure 250A to be self-aligned with each other without alignment errors. Furthermore, contact resistance may be greatly improved by stably securing the contact area between the buried conductive structure 150A and the conductive through structure 250A through stable self-alignment. Specifically, after forming the hole CH′, the wet etching process may be applied to expand a final hole CH in the width direction, thereby additionally increasing the contact area.

By way of summation and review, a method of forming a conductive through structure penetrating through a semiconductor substrate is desired in order to dispose at least some wiring of the BEOL wiring (e.g., a power line) on a backside of the substrate and connect the same with some wiring.

An aspect of the present disclosure is to provide a semiconductor device capable of self-aligning a buried conductive structure and a conductive through structure. That is, according to example embodiments, a conductive through structure may be self-aligned with the buried conductive structure without an alignment error. Furthermore, contact resistance may be greatly improved by stably securing a contact area between the buried conductive structure and the conductive through structure through stable self-alignment.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor device, comprising:
a substrate having a first surface and a second surface opposing each other;
a fin-type active pattern on the first surface of the substrate and extending in a first direction;
a gate structure crossing the fin-type active pattern and extending in a second direction, intersecting the first direction;
a source/drain region on the fin-type active pattern at a side of the gate structure;
an interlayer insulating unit on the substrate and covering the source/drain region;
a contact structure penetrating through a portion of the interlayer insulating unit and connected to the source/drain region;
a buried conductive structure extending in the interlayer insulating unit in a direction perpendicular to the first surface of the substrate, the buried conductive structure being electrically connected to the contact structure;
a conductive through structure extending from the second surface of the substrate toward the first surface of the substrate and contacting the buried conductive structure, the conductive through structure having a first width at a level adjacent to the first surface, wider than a second width at a level adjacent to the second surface, and a contact portion, in which the buried conductive structure and the conductive through structure are in contact with each other, having a continuous side surface; and
a power transmission line on the second surface of the substrate and connected to the conductive through structure.

2. The semiconductor device as claimed in claim 1, wherein the conductive through structure has a convex or concave upper surface.

3. The semiconductor device as claimed in claim 1, wherein the conductive through structure has a width that gradually narrows as it approaches the second surface of the substrate.

4. The semiconductor device as claimed in claim 1, wherein the buried conductive structure and the conductive through structure have continuous side surfaces.

5. The semiconductor device as claimed in claim 1, wherein:
the conductive through structure penetrates through the substrate and extends into the interlayer insulating unit, and
the contact portion is on the first surface of the substrate.

6. The semiconductor device as claimed in claim 5, wherein a side surface of the conductive through structure has a step portion on the first surface of the substrate.

7. The semiconductor device as claimed in claim 5, wherein:
the buried conductive structure includes a first contact plug and a first conductive barrier surrounding a side surface and a lower surface of the first contact plug, and
the conductive through structure includes a second contact plug, a second insulating liner surrounding a side surface of the second contact plug, and a second conductive barrier between the second contact plug and the second insulating liner and extending to an upper surface of the second contact plug.

8. The semiconductor device as claimed in claim 1, wherein:
the buried conductive structure extends into the substrate, and
the contact portion is in the substrate.

9. The semiconductor device as claimed in claim 8, wherein a side surface of the buried conductive structure has a step portion on the first surface of the substrate.

10. The semiconductor device as claimed in claim 8, wherein:
the buried conductive structure includes a first contact plug, a first insulating liner surrounding a side surface of the first contact plug, and a first conductive barrier surrounding a side surface and a lower surface of the first contact plug between the first contact plug and the first insulating liner, and
the conductive through structure includes a second contact plug, a second insulating liner surrounding a side surface of the second contact plug, and a second conductive barrier disposed between the second contact plug and the second insulating liner and extending to an upper surface of the second contact plug.

11. The semiconductor device as claimed in claim 1, wherein:
an upper surface of the conductive through structure has a convex or concave portion, and
the convex or concave portion of the conductive through structure horizontally overlaps the first surface of the substrate.

12. The semiconductor device as claimed in claim 1, wherein the contact structure has an extension portion extending in the second direction and connected to an upper surface of the buried conductive structure.

13. The semiconductor device as claimed in claim 1, further comprising a first wiring structure on the interlayer insulating unit and having a first wiring layer connected to the contact structure, an upper surface of the buried conductive structure being connected to the first wiring layer and being connected to the contact structure through the first wiring layer.

14. The semiconductor device as claimed in claim 1, further comprising a second wiring structure on the second surface of the substrate and having a second wiring layer connected to the power transmission line.

15. The semiconductor device as claimed in claim 1, further comprising semiconductor patterns spaced apart from each other in a direction perpendicular to the first surface of the substrate on the fin-type active pattern, the gate structure including a gate electrode surrounding each of the semiconductor patterns and extending in the second direction, and a gate insulating film between each of the semiconductor patterns and the gate electrode.

16. A semiconductor device, comprising:
a substrate having a first surface and a second surface opposing each other;
a fin-type active pattern on the first surface of the substrate and extending in a first direction;
a gate structure crossing the fin-type active pattern and extending in a second direction, intersecting the first direction;
a source/drain region on the fin-type active pattern at a side of the gate structure;
an interlayer insulating unit on the substrate and covering the source/drain region;
a contact structure penetrating through a portion of the interlayer insulating unit and connected to the source/drain region;
a buried conductive structure extending in the interlayer insulating unit in a direction perpendicular to the first surface of the substrate, the buried conductive structure being electrically connected to the contact structure;
a conductive through structure penetrating through the substrate and extending to the interlayer insulating unit to have a contact with the buried conductive structure, an upper surface of the conductive through structure in contact with the buried conductive structure being a convex surface, and the conductive through structure including a portion extending to the interlayer insulating unit and having a side surface continuous with a side surface of the buried conductive structure; and
a power transmission line on the second surface of the substrate and connected to the conductive through structure.

17. The semiconductor device as claimed in claim 16, wherein the conductive through structure has a continuous side surface, a width of the conductive through structure gradually narrowing as it approaches the second surface of the substrate.

18. The semiconductor device as claimed in claim 16, wherein a side surface of the conductive through structure has a step portion on the first surface of the substrate.

19. A semiconductor device, comprising:
a substrate having a first surface and a second surface opposing each other;
a fin-type active pattern on the first surface of the substrate and extending in a first direction;
a gate structure crossing the fin-type active pattern and extending in a second direction, intersecting the first direction;
a source/drain region on the fin-type active pattern at a side of the gate structure;
an interlayer insulating unit on the substrate and covering the source/drain region;
a contact structure penetrating through the interlayer insulating unit and connected to the source/drain region;
a buried conductive structure electrically connected to the contact structure and extending into the substrate from the interlayer insulating unit;
a conductive through structure extending from the second surface of the substrate and contacting the buried conductive structure, an upper surface of the conductive through structure in contact with the buried conductive structure being a non-flat surface, and the conductive through structure having a side surface continuous with a side surface of a portion of the buried conductive structure in the substrate; and
a power transmission line on the second surface of the substrate and connected to the conductive through structure.

20. The semiconductor device as claimed in claim 19, wherein:
the conductive through structure and the portion of the buried conductive structure in the substrate have a width that gradually decreases as it approaches the second surface of the substrate, and
a side surface of the buried conductive structure has a step portion on the first surface of the substrate.
